(19) United States
(12) Patent Application Publication
(10) Pub. No.: US 2021/0041785 A1
(43) Pub. Date: Feb. 11, 2021

(54) PROCESS CONTROL OF ELECTRIC FIELD GUIDED PHOTORESIST BAKING PROCESS

(71) Applicant: Applied Materials, Inc., Santa Clara, CA (US)

(72) Inventors: Huixiong DAI, San Jose, CA (US); Mangesh Ashok BANGAR, San Jose, CA (US); Pinkesh Rohit SHAH, San Jose, CA (US); Christopher Siu Wing NGAI, Burlingame, CA (US); Srinivas D. NEMANI, Sunnyvale, CA (US); Ellie Y. YIEH, San Jose, CA (US)

(21) Appl. No.: 16/989,698

(22) Filed: Aug. 10, 2020

Related U.S. Application Data
(60) Provisional application No. 62/884,937, filed on Aug. 9, 2019.

(51) Int. Cl. G03F 7/16; G03F 7/20

(52) U.S. Cl. CPC G03F 7/168; G03F 7/70; G03F 7/162

(57) ABSTRACT

Methods and apparatuses for minimizing line edge/width roughness in lines formed by photolithography are provided. A method of processing a substrate is provided. The method includes applying a photoresist layer that includes a photoacid generator to a multi-layer disposed on the substrate. The multi-layer includes an underlayer. Further, the method includes exposing a first portion of the photoresist layer unprotected by a photomask to a radiation light in a lithographic exposure process. A thermal energy is provided to the photoresist layer and the multi-layer in a post-exposure baking process. The multi-layer is disposed beneath the photoresist layer. An electric field or a magnetic field is applied to photoresist layer and the multi-layer while performing the post-exposure baking process. An additive within the underlayer is driven in a vertical direction into the photoresist layer. The additive assist in distribution of a photoacid throughout the photoresist layer during the post-exposure baking process.

### CROSS REFERENCE TO RELATED APPLICATIONS

This application claims benefit of U.S. Patent Application Ser. No. 62/884,937, filed Aug. 9, 2019, which is incorporated by reference in its entirety.

### BACKGROUND

### Field

The present disclosure generally relates to methods and apparatuses for processing a substrate, and more specifically to methods and apparatuses for enhancing photoresist profile control.

### Description of the Related Art

Integrated circuits have evolved into complex devices that can include millions of components (e.g., transistors, capacitors and resistors) on a single chip. Photolithography may be used to form components on a chip. Generally the process of photolithography involves a few basic stages. Initially, a photoresist layer is formed on a substrate. The photoresist layer may be formed by, for example, spin-coating. The photoresist layer may include a resist resin and a photoacid generator. The photoacid generator, upon exposure to electromagnetic radiation in the subsequent exposure stage, alters the solubility of the photoresist in the development process. The electromagnetic radiation may have any suitable wavelength, such as a wavelength in the extreme ultra violet region. The electromagnetic radiation may be from any suitable source, such as, for example, a 193 nm ArF laser, an electron beam, an ion beam, or other source. Excess solvent may then be removed in a pre-exposure bake process.

In an exposure stage, a photomask or reticle may be used to selectively expose certain regions of a photoresist layer disposed on the substrate to electromagnetic radiation. Other exposure methods may be maskless exposure methods. Exposure to light may decompose the photoacid generator, which generates acid and results in a latent acid image in the resist resin. After exposure, the substrate may be heated in a post-exposure bake process. During the post-exposure bake process, the acid generated by the photoacid generator reacts with the resist resin in the photoresist layer, changing the solubility of the resist of the photoresist layer during the subsequent development process.

After the post-exposure bake, the substrate, and, particularly, the photoresist layer may be developed and rinsed. After development and rinsing, a patterned photoresist layer is then formed on the substrate, as shown in FIG. 1. FIG. 1 depicts an exemplary top sectional view of the substrate 100 having the patterned photoresist layer 104 disposed on a target material 102 to be etched. Openings 106 are defined between the patterned photoresist layer 104, after the development and rinse processes, exposing the underlying target material 102 for etching to transfer features onto the target material 102. However, inaccurate control or low resolution of the lithography exposure process may cause in poor critical dimension of the patterned photoresist layer 104, resulting in unacceptable line width roughness (LWR) 108. Furthermore, during the exposure and/or baking process, photoacid (shown as in FIG. 1) generated from the photoacid generator may randomly diffuse to any regions, including the regions protected under the mask unintended to be diffused, thus creating undesired wigging or roughness profile 150 at the edge or interface of the patterned photoresist layer 104 interfaced with the openings 106. Large line width roughness (LWR) 108 and roughness profile 150 (i.e. an undesired wiggling) of the patterned photoresist layer 104 may result in inaccurate feature transfer to the target material 102, thus, eventually leading to device failure and yield loss.

Therefore, there is a need for a method and an apparatus to control line width roughness (LWR) and enhance resolution as well as dose sensitivity so as to obtain a patterned photoresist layer with desired critical dimensions.

### SUMMARY

Examples of the present disclosure include a method for performing a post-exposure bake process with desired process parameters control over pre- or post-exposure baking process. In one example, a method of processing a substrate is provided. The method includes applying a photoresist layer that includes a photoacid generator to a multi-layer disposed on the substrate. The multi-layer includes an underlayer. Further, the method includes exposing a first portion of the photoresist layer unprotected by a photomask to a radiation light in a lithographic exposure process. A thermal energy is provided to the photoresist layer and the multi-layer in a post-exposure baking process. The multi-layer is disposed beneath the photoresist layer. An electric field or a magnetic field is applied to photoresist layer and the multi-layer while performing the post-exposure baking process. An additive within the underlayer is driven in a vertical direction into the photoresist layer. The additive assist in distribution of a photoacid throughout the photoresist layer during the post-exposure baking process.

In another example, a method of processing a substrate includes applying a photoresist layer disposed on a substrate, the substrate having a multi-layer disposed thereon. The method further includes exposing a first portion of the photoresist layer unprotected by a photomask to a radiation light in a lithographic exposure process. A post-exposure baking process is performed on the photoresist layer. The method further includes, supplying a power in a pulse mode to generate an electric field while performing the post-exposure baking process. An additive in the multi-layer is vertically diffused into the photoresist layer. The additive assist in distribution of a photoacid throughout the photoresist layer during the post-exposure baking process.

In yet another example, a method of processing a substrate includes

applying a photoresist layer on an underlayer disposed on a substrate. The underlayer is an organic material. The method includes exposing a first portion of the photoresist layer unprotected by a photomask to a radiation light in a lithographic exposure process. A thermal energy is provided to the photoresist layer and the underlayer disposed on the substrate in a post-exposure baking process. Power is supplied in a pulse mode to generate an electric field while performing the post-exposure baking process. The method further includes orienting photoacid formed in the first portion of the photoresist layer while generating the electric field to the photoresist layer. The photoacid is oriented by vertical movement of an additive in the underlayer. The additive is vertically diffused from the underlayer to the first portion of the photoresist layer.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is to be noted, however, that the appended drawings illustrate only typical examples of this disclosure and are therefore not to be considered limiting of its scope, for the disclosure may admit to other equally effective examples.

FIG. 1 depicts a top view of an exemplary structure of a patterned photoresist layer disposed on a substrate conventionally in the art;

FIG. 2 is a schematic cross-sectional view of an apparatus for processing a substrate, according to one example;

FIG. 3 is a top view of one example of an electrode assembly disposed in the apparatus of FIG. 2;

FIG. 4 depict an acid distribution control of a photoresist layer disposed on a film structure during an exposure process;

FIG. 5 depicts an acid distribution control of a photoresist layer on a film structure with a desired profile during a post-exposure baking process; and

FIG. 6 is a flow diagram of one method of control acid distribution of a photoresist layer during a pre- or post-exposure baking process.

To facilitate understanding, identical reference numerals have been used, wherever possible, to designate identical elements that are common to the Figures. Additionally, elements of one example may be advantageously adapted for utilization in other examples described herein.

### DETAILED DESCRIPTION

Methods for enhancing profile control of a photoresist layer formed by photolithography are provided. The methods disclosed herein are directed to mitigating stochastic effects that can give rise to local, random printing failures, such as missing contacts, scummed contacts, or microbridges within the photoresist. The random or local variability that occurs between structures in the photoresist that should in principle be substantially identically are referred to herein as “stochastic effects.” This local or random variability can include critical dimension variability on a scale of one or more micrometers to about one or more nanometers. Additionally, critical dimension changes may also be caused by non-uniformities in a substrate below the photoresist, or caused by particles in the photoresist, a rinse, or a developer liquid.

Advantageously, the methods disclosed herein mitigate the stochastic effects in the photoresist. Accordingly, the diffusion of photoacid generated by a photoacid generator during a post-exposure bake procedure that contributes to line edge/width roughness may be mitigated by control the process parameters during the pre- or post-exposure bake procedure within a desired range. The electric field application controls the diffusion and distribution of the acids generated by the photoacid generator in the photoresist layer as well as in an underlayer disposed in a film structure under the photoresist layer, thus preventing the line edge/width roughness that results from random diffusion. Suitable process parameters controlled during the pre- or post-exposure bake process includes voltage level for controlling the electric field as generated during the baking process, continuous or pulse mode of a voltage power for generating the electric field, temperature control to the substrate, and electric field applied duration during the pre- or post-exposure bake process.

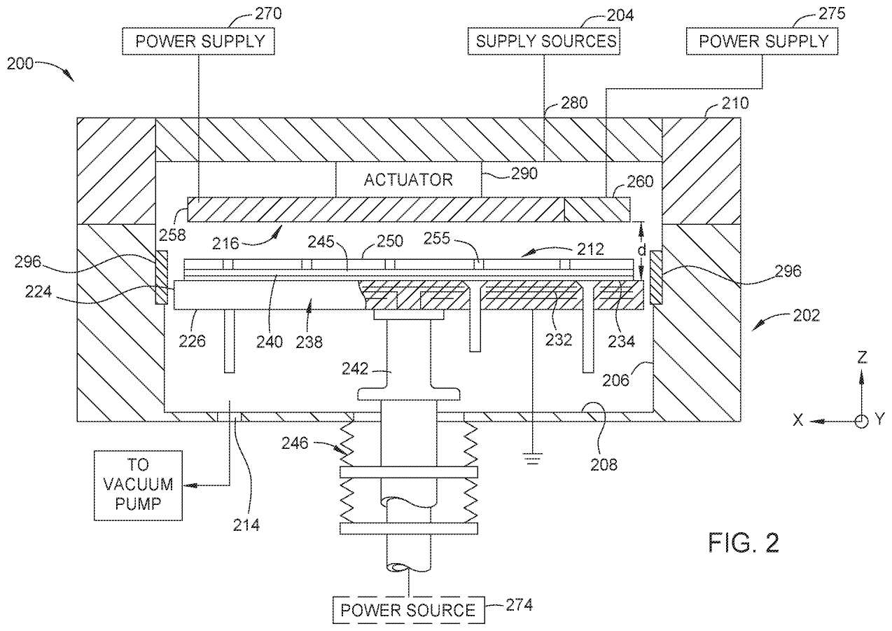

FIG. 2 is a schematic cross-sectional view of an apparatus for processing a substrate, according to one example. As shown in the example of FIG. 2, the apparatus may be in the form of the processing chamber 200. In other examples, the processing chamber 200 may not be coupled to a vacuum source.

The processing chamber 200 may be an independent stand-alone processing chamber. Alternatively, the processing chamber 200 may be part of a processing system, such as, for example, an in-line processing system, a cluster processing system, or a track processing system. The processing chamber 200 is described in detail below and may be used for a pre-exposure bake, a post-exposure bake, and/or other processing steps.

The processing chamber 200 includes chamber walls 202, an electrode assembly 216, and a substrate support assembly 238. The chamber walls 202 include sidewalls 206, a lid assembly 210, and a bottom 208. The chamber walls 202 partially enclose a processing volume 212. The processing volume 212 is accessed through a substrate transfer port (not shown) configured to facilitate movement of a substrate 240 into and out of the processing chamber 200. In examples where the processing chamber 200 is part of a processing system, the substrate transfer port may allow for the substrate 240 to be transferred to and from an adjoining transfer chamber.

A pumping port 214 may optionally be disposed through one of the lid assembly 210, sidewalls 206 or bottom 208 of the processing chamber 200 to couple the processing volume 212 to an exhaust port. The exhaust port couples the pumping port 214 to various vacuum pumping components, such as a vacuum pump. The pumping components may reduce the pressure of the processing volume 212 and exhaust any gases and/or process by-products out of the processing chamber 200. The processing chamber 200 may be coupled to one or more supply sources 204 for delivering one or more source compounds into the processing volume 212.

The substrate support assembly 238 is centrally disposed within the processing chamber 200. The substrate support assembly 238 supports the substrate 240 during processing. The substrate support assembly 238 may include a body 224 that encapsulates at least one embedded heater 232. In some examples, the substrate support assembly 238 may be an electrostatic chuck. The heater 232, such as a resistive element, is disposed in the substrate support assembly 238. The heater 232 controllably heats the substrate support assembly 238 and the substrate 240 positioned thereon to a predetermined temperature. The heater 232 is configured to quickly ramp up the temperature of the substrate 240 and to accurately control the temperature of the substrate 240. In some examples, the heater 232 is connected to and controlled by a power source 274. The power source 274 may alternatively or additionally apply power to the substrate support assembly 238. The power source 274 may be configured similarly to the power source 270, discussed below. Furthermore, it is noted that the heater 232 may be disposed from other locations of the processing chamber 200. For example, the heater 232 may be disposed from a chamber wall, chamber liner, edge ring that circumscribes the substrate, the chamber ceiling and the like, as needed to provide thermal energy to the substrate 240 disposed on the substrate support assembly 238.

In some examples, the substrate support assembly 238 may be configured to rotate. In some examples, the substrate support assembly 238 is configured to rotate about the z-axis. The substrate support assembly 238 may be configured to continuously or constantly rotate, or the substrate support assembly 238 may be configured to rotate in a step-wise or indexing manner. For example, the substrate support assembly 238 may rotate a predetermined amount, such as 90°, 180°, or 270°. The substrate support assembly 238 may stop rotating for a predetermined amount of time.

In one example, the substrate support assembly 238 has a first surface 234 and a second surface 226. The first surface 234 is opposite the second surface 226. The first surface 234 is configured to support the substrate 240. The second surface 226 has a stem 242 coupled thereto. The substrate 240 may be any type of substrate, such as a dielectric substrate, a glass substrate, a semiconductor substrate, or a conductive substrate. The substrate 240 may include a material layer 245 disposed thereon. The material layer 245 may be any desired layer. In other examples, the substrate 240 may include more than one material layer 245. The substrate 240 also has a photoresist layer 250 disposed over the material layer 245. The substrate 240 has been previously exposed to electromagnetic radiation in an exposure stage of a photolithography process. The photoresist layer 250 has latent image lines 255 formed therein from the exposure stage. The latent image lines 255 may be substantially parallel. In other examples, the latent image lines 255 may not be substantially parallel. Also as shown, the first surface 234 of the substrate support assembly 238 is separated from the electrode assembly 216 by a distance d in a z-direction. The stem 242 is coupled to a lift system (not shown) for moving the substrate support assembly 238 between an elevated processing position (as shown) and a lowered substrate transfer position. The lift system may accurately and precisely control the position of the substrate 240 in the z-direction. In some examples, the lift system may also be configured to move the substrate 240 in an x-direction, a y-direction, or the x-direction and the y-direction. The stem 242 additionally provides a conduit for electrical and thermocouple leads between the substrate support assembly 238 and other components of the processing chamber 200. A bellows 246 is coupled to the substrate support assembly 238 to provide a vacuum seal between the processing volume 212 and the atmosphere outside the processing chamber 200 and facilitate movement of the substrate support assembly 238 in the z-direction.

The lid assembly 210 may optionally include an inlet 280 through which gases provided by the supply sources 204 may enter the processing chamber 200. The supply sources 204 may optionally controllably pressurize the processing volume 212 with a gas, such as nitrogen, argon, helium, other gases, or combinations thereof. The gases from the supply sources 204 may create a controlled environment within the processing chamber 200. An actuator 290 may be optionally coupled between the lid assembly 210 and the electrode assembly 216. The actuator 290 is configured to move the electrode assembly 216 in one or more of the x, y, and z directions. The x and y directions are referred to herein as the lateral directions or dimensions. The actuator 290 enables the electrode assembly 216 to scan the surface of the substrate 240. The actuator 290 also enables the distance d to be adjusted. In some examples, the electrode assembly 216 is coupled to the lid assembly 210 by a fixed stem (not shown). In other examples, the electrode assembly 216 may be coupled to the inside of the bottom 208 of the processing chamber 200, to the second surface 226 of the substrate support assembly 238, or to the stem 242. In still other examples, the electrode assembly 216 may be embedded between the first surface 234 and the second surface 226 of the substrate support assembly 238.

The electrode assembly 216 includes at least a first electrode 258 and a second electrode 260. As shown, the first electrode 258 is coupled to a power source 270, and the second electrode 260 is coupled to an optional power supply 275. In other examples, one of the first electrode 258 and the second electrode 260 may be coupled to a power supply and the other electrode may be coupled to a ground. In some examples, the first electrode 258 and the second electrode 260 are coupled to a ground and the power source 274 that delivers power to the substrate support is a bipolar power supply that switches between a positive and negative bias. In some examples, the power source 270 or the power supply 275 may be coupled to both the first electrode 258 and the second electrode 260. In other examples, the power source 270 or the power supply 275 may be coupled to the first electrode 258, the second electrode 260, and the substrate support assembly 238. In such examples, the pulse delay to each of the first electrode 258, the second electrode 260, and the substrate support assembly 238 may be different. The electrode assembly 216 may be configured to generate an electric field parallel to the x-y plane defined by the first surface 234 of the substrate support assembly 238. For example, the electrode assembly 216 may be configured to generate an electric field in one of the y direction, x direction or other direction in the x-y plane.

The power source 270 and the power supply 275 are configured to supply, for example, between about 500 V and about 100 kV to the electrode assembly 216. The power source 270 and the power supply 275 are configured to generate an electric field having a strength between about 0.1 MV/m and about 100 MV/m. In some examples, the power source 274 may also be configured to provide power to the electrode assembly 216. In some examples, any or all of the power source 270, the power source 274, or the power supply 275 are a pulsed direct current (DC) power supply. The pulsed DC wave may be from a half-wave rectifier or a full-wave rectifier. The DC power may have a frequency of between about 10 Hz and 1 MHz. The duty cycle of the pulsed DC power may be from between about 5% and about 95%, such as between about 20% and about 60%. In some examples, the duty cycle of the pulsed DC power may be between about 20% and about 40%. In other examples, the duty cycle of the pulsed DC power may be about 60%. The rise and fall time of the pulsed DC power may be between about 1 ns and about 1000 ns, such as between about 10 ns and about 500 ns. In other examples, the rise and fall time of the pulsed DC power may be between about 10 ns and about 100 ns. In some examples, the rise and fall time of the pulsed DC power may be about 500 ns. In some examples, any or all of the power source 270, the power source 274, and the power supply 275 are an alternating current power supply. In other examples, any or all of the power source 270, the power source 274, and the power supply 275 are a direct current power supply.

In some examples, any or all of the power source 270, the power source 274, and the power supply 275 may use a DC offset. The DC offset may be, for example, between about 0% and about 75% of the applied voltage, such as between about 5% and about 60% of the applied voltage. In some examples, the first electrode 258 and the second electrode 260 are pulsed negatively while the substrate support assembly 238 is also pulsed negatively. In these examples, the first electrode 258 and the second electrode 260 are the substrate support assembly 238 are synchronized but offset in time. For example, the first electrode 258 may be at the “one” state while the substrate support assembly is at the “zero” state,” then the substrate support assembly 238 in the one state while the first electrode 258 is at the zero state.

The electrode assembly 216 spans approximately the width of the substrate support assembly 238. In other examples, the width of the electrode assembly 216 may be less than that of the substrate support assembly 238. For example, the electrode assembly 216 may span between about 10% to about 80%, such as about 20% and about 40%, the width of the substrate support assembly 238. In examples where the electrode assembly 216 is less wide than the substrate support assembly 238, the actuator 290 may scan the electrode assembly 216 across the surface of the substrate 240 positioned on the first surface 234 of the substrate support assembly 238. For example, the actuator 290 may scan such that the electrode assembly 216 scans the entire surface of the substrate 240. In other examples, the actuator 290 may scan only certain portions of the substrate 240. Alternatively, the substrate support assembly 238 may scan underneath the electrode assembly 216.

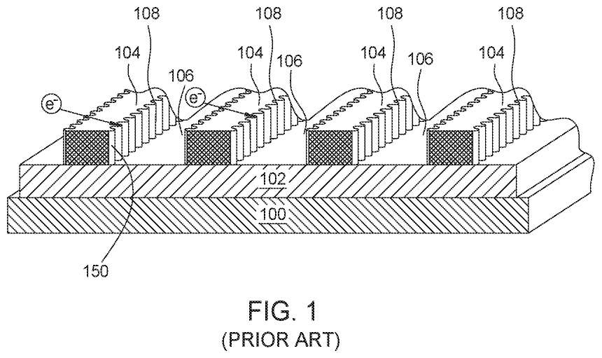

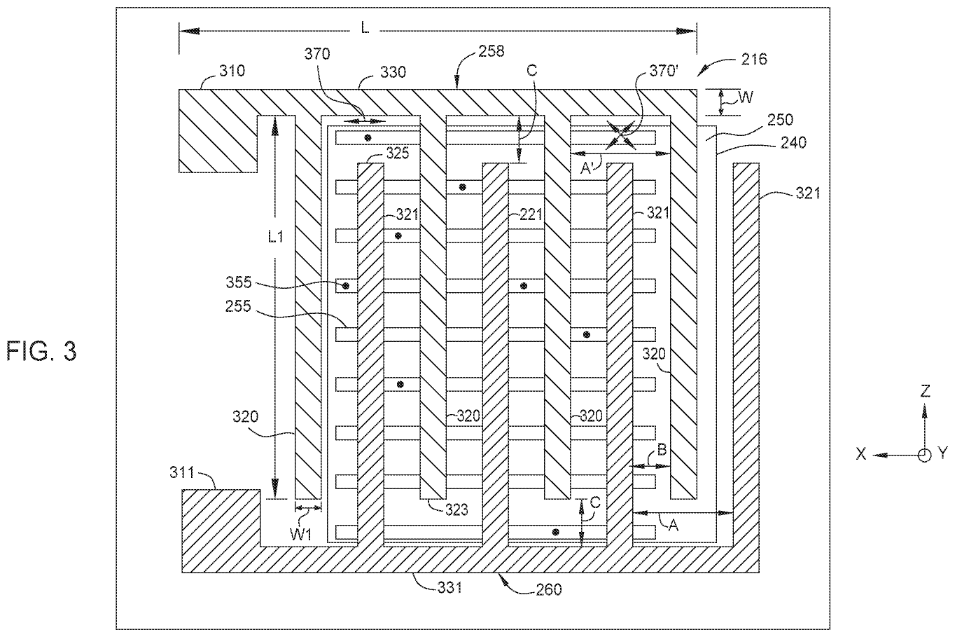

In some examples, one or more magnets 296 may be positioned in the processing chamber 200. In the example shown in FIG. 1, the magnets 296 are coupled to the inside surface of the sidewalls 206. In other examples, the magnets 296 may be positioned in other locations within the processing chamber 200 or outside the processing chamber 200. The magnets 296 may be, for example, permanent magnets or electromagnets. Representative permanent magnets include ceramic magnets and rare earth magnets. In examples where the magnets 296 include electromagnets, the magnets 296 may be coupled to a power source (not shown). The magnets 296 are configured to generate a magnetic field in a direction perpendicular or parallel to the direction of the electric field lines generated by the electrode assembly 216 at the first surface 234 of the substrate support assembly 238. For example, the magnets 296 may be configured to generate a magnetic field in the x-direction when the electric field generated by the electrode assembly 216 is in the y-direction. The magnetic field drives a charged species 355 (shown in FIG. 2) and polarized species (not shown) generated by the photoacid generators in the photoresist layer 250 in a direction perpendicular to the magnetic field, such as the direction parallel with the latent image lines 255. By driving the charged species 355 and polarized species in a direction parallel with the latent image lines 255, line roughness may be reduced. The uniform directional movement of the charged species 355 and polarized species is shown by the double headed arrow 370 in FIG. 3. In contrast, when a magnetic field is not applied, the charged species 355 and polarized species may move randomly, as shown by the arrows 370′.

Continuing to refer to FIG. 3, the electrode assembly 216 includes at least the first electrode 258 and the second electrode 260. The first electrode 258 includes a first terminal 310, a first support structure 330, and one or more antennas 320. The second electrode 260 includes a second terminal 311, a second support structure 331, and one or more antennas 321. The first terminal 310, the first support structure 330, and the one or more antennas 320 of the first electrode 258 may form a unitary body. Alternatively, the first electrode 258 may include separate portions that may be coupled together. For example, the one or more antennas 320 may be detachable from the first support structure 330. The second electrode 260 may similarly be a unitary body or be made of separate detachable components. The first electrode 258 and the second electrode 260 may be fabricated by any suitable technique. For example, the first electrode 258 and the second electrode 260 may be fabricated by machining, casting, or additive manufacturing.

The first support structure 330 may be made from a conductive material, such as metal. For example, the first support structure 330 may be made of a non-metal. Examples of a non-metal include silicon, polysilicon, silicon carbide, molybdenum, aluminum, copper, graphite, silver, platinum, gold, palladium, zinc, other materials, or mixtures thereof. The first support structure 330 may have any desired dimensions. For example, the length L of the first support structure 330 may be between about 25 mm and about 450 mm, for example, between about 100 mm and about 300 mm. In some examples, the first support structure 330 has a length L approximately equal to a diameter of a standard semiconductor substrate. In other examples, the first support structure 330 has a length L that is larger or smaller than the diameter of a standard semiconductor substrate. For example, in different representative examples, the length L of the first support structure 330 may be about 25 mm, about 51 mm, about 76 mm, about 100 mm, about 150 mm, about 200 mm, about 300 mm, or about 450 mm. The width W of the first support structure 330 may be between about 2 mm and about 25 mm. In other examples, the width W of the first support structure 330 is less than about 2 mm. In other examples, the width W of the first support structure 330 is greater than about 25 mm. A thickness of the first support structure 330 may be between about 1 mm and about 10 mm, such as between about 2 mm and about 8 mm, such as about 5 mm. In some examples, the first support structure 330 may be square, cylindrical, rectangular, oval, rods, or other shapes. Examples of the first support structure 330 having curved exterior surfaces may avoid, i.e. prevent arcing.

The first support structure 330 may be made of the same materials as the second support structure 331. The range of dimensions suitable for the first support structure 330 is also suitable for the second support structure 331. In some examples, the first support structure 330 and the second support structure 331 are made of the same material. In other examples, the first support structure 330 and the second support structure 331 are made of different materials. The lengths L, widths W, and the thicknesses of the first support structure 330 and the second support structure 331 may be the same or different.

The one or more antennas 320 of the first electrode 258 may also be made from a conductive material. The one or more antennas 320 may be made from the same materials as the first support structure 330. The one or more antennas 320 of the first electrode 258 may have any desired dimensions. For example, a length L1 of the one or more antennas 320 may be between about 25 mm and about 450 mm, for example, between about 100 mm and about 300 mm. In some examples, the first support structure 330 has a length L1 approximately equal to the diameter of a standard substrate. In other examples, the length L1 of the one or more antennas 320 may be between about 75% and 90% of the diameter of a standard substrate. A width W1 of the one or more antennas 320 may be between about 2 mm and about 25 mm. In other examples, the width W1 of the one or more antennas 320 is less than about 2 mm. In other examples, the width W1 of the one or more antennas 320 is greater than about 25 mm. The thickness of the one or more antennas 320 may be between about 1 mm and about 10 mm, such as between about 2 mm and about 8 mm. The one or more antennas 320 may have a cross-section that is square, rectangular, oval, circular, cylindrical, or another shape. Examples of the first support structure 330 having round exterior surfaces may assist in preventing arcing.

Each of the antennas 320 may have the same dimensions. Alternatively, some of the one or more antennas 320 may have different dimensions than one or more of the other antennas 320. For example, some of the one or more antennas 320 may have different lengths L1 than one or more of the other antennas 320. Each of the one or more antennas 320 may be made of the same material. In other examples, some of the antennas 320 may be made of a different material than other antennas 320.

The antennas 321 may be made of the same range of materials as the antennas 320. The range of dimensions suitable for the antennas 320 is also suitable for the antennas 321. In some examples, the antennas 320 and the antennas 321 are made of the same material. In other examples, the antennas 320 and the antennas 321 are made of different materials. The lengths L1, widths W1, and a thicknesses of the antennas 320 and the antennas 321 may be the same or different.

The antennas 320 may include between 1 and about 40 antennas 320. For example, the antennas 320 may include between about 4 and about 40 antennas 320, such as between about 10 and about 20 antennas 320. In other examples, the antennas 320 may include more than 40 antennas 320. In some examples, each of the antennas 320 may be substantially perpendicular to the first support structure 330. For example, in examples where the first support structure 330 is straight, each antenna 320 may be substantially parallel to the first support structure 330. Each of the antennas 320 may be substantially parallel to each of the other antennas 320. Each of the antennas 321 may be similarly positioned with respect to the second support structure 331 and each other antenna 321.

Each of the antennas 320 has a terminal end 323. Each of the antennas 321 has a terminal end 325. A distance C is defined between the first support structure 330 and the terminal end 325. A distance C′ is defined between the second support structure 331 and the terminal end 323. Each of the distances C and C′ may be between about 1 mm and about 10 mm. In other examples, the distances C and C′ may be less than about 1 mm or greater than about 10 mm. In some examples, the distance C and the distance C′ are equal. In other examples, the distance C and the distance C′ are different.

A distance A is defined between facing surfaces of one of the antennas 321 and an adjacent one of the antennas 321. The distance A′ is defined between facing surfaces of one antenna 320 and an adjacent one the antennas 320. The distances A and A′ may be greater than about 6 mm. For example, the distances A and A′ may be between about 6 mm and about 20 mm, such as between about 10 mm and about 15 mm. The distances A and A′ between each adjacent antennas 321, 320 may be the same or different. For example, the distances A′ between the first and second, second and third, and third and fourth antennas of the one or more antennas 320 may be different. In other examples, the distances A′ may be the same.

A distance B is defined between facing surfaces of one of the antennas 320 and an adjacent one of the antennas 321. The distance B may be, for example, greater than about 1 mm. For example, the distance B may be between about 2 mm and about 10 mm, such as between about 4 mm and about 6 mm. The distance B defined between may be the same, each distance B may be different, or some distances B may be the same and some distances B may be different. Adjusting the distance B allows for easy control of the electric field strength.

The antennas 320, 321 may be oriented in an alternating arrangement above the photoresist layer 250. For example, the antennas 320 of the first electrode 258 and the antennas 321 of the second electrode 260 may be positioned such that at least one of the antennas 320 is positioned between two of the antennas 321. Additionally, at least one antenna 321 may be positioned between two of the antennas 320. In some examples, all but one of the antennas 320 is positioned between two of the antennas 321. In those examples, all but one of the antennas 321 may be positioned between two of the antennas 320. In some examples, the antennas 320 may each have only one antenna 320 and the antennas 321 may have only one antenna 321.

In some examples, the first electrode 258 includes the first terminal 310, and the second electrode 260 has the second terminal 311. The first terminal 310 may be a contact between the first electrode 358 and the power source 270, the power supply 275, or a ground. The second terminal 311 may be a contact between the second electrode 260 and the power source 270, the power source 270, or a ground. The first terminal 310 and the second terminal 311 are shown as being at one end of the first electrode 258 and the second electrode 260, respectively. In other examples, the first terminal 310 and the second terminal 311 may be positioned at other locations on the first electrode 258 and the second electrode, respectively. The first terminal 310 and the second terminal 311 have different shapes and sizes than the first support structure 330 and the second support structure 331, respectively. In other examples, the first terminal 310 and the second terminal 311 may have generally the same shapes and sizes as the first support structure 330 and the second support structure 331, respectively.

In operation, a voltage may be supplied from a power supply, such as the power source 270, the power source 274, or the power supply 275, to the first terminal 310, the second terminal 311, and/or the substrate support assembly 238. The supplied voltage creates an electric field between each antenna of the one or more antennas 320 and each antenna of the one or more antennas 321. The electric field will be strongest between an antenna of the one or more antennas 320 and an adjacent antenna of the one or more antennas 321. The interleaved and aligned spatial relationship of the antennas 320, 321 produces an electric field in a direction parallel to the plane defined by the first surface 234 of the substrate support assembly 238. The substrate 240 is positioned on the first surface 234 such that the latent image lines 255 are parallel to the electric field lines generated by the electrode assembly 216. Since the charged species 355 are charged, the charged species 355 are affected by the electric field. The electric field drives the charged species 355 generated by the photoacid generators in the photoresist layer 250 in the direction of the electric field. By driving the charged species 355 in a direction parallel with the latent image lines 255, line edge roughness may be reduced. A uniform directional movement is shown by the double headed arrow 370. In contrast, when a voltage is not applied to the first terminal 310 or the second terminal 311, an electric field is not created to drive the charged species 355 in any particular direction. As a result, the charged species 355 may move randomly, as shown by the arrows 370′, which may result in wariness or line roughness.

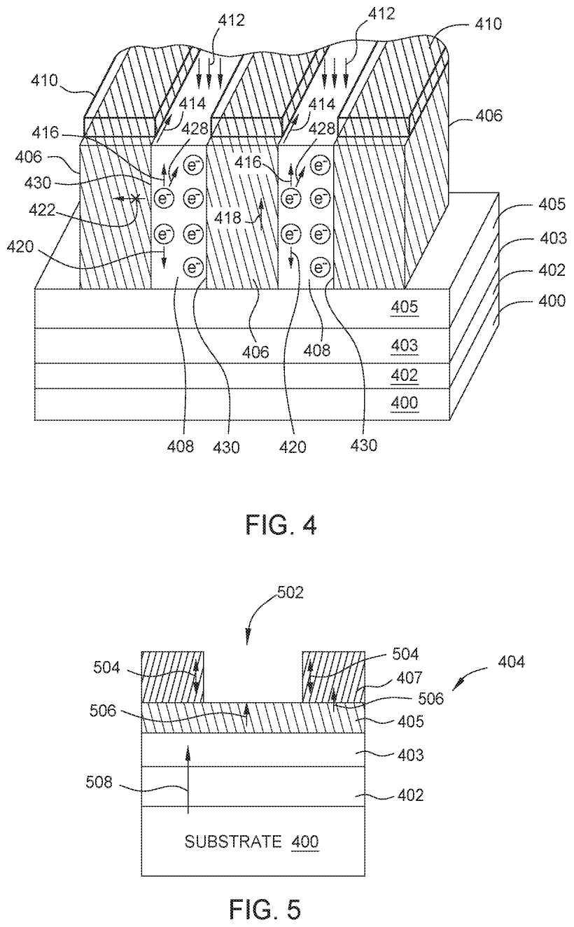

FIG. 4 depicts a film structure 404 disposed on a substrate 400 during a lithography exposure process and pre- or post-exposure baking process. A photoresist layer 407 is disposed on the film structure 404. The film structure 404 includes an underlayer 405 disposed on a hardmask layer 403 and further on a target layer 402. The target layer 402 is later patterned for forming the desired device features in the target layer 402. In one example, the underlayer 405 may be an organic material, an inorganic material, or a mixture of organic or inorganic materials. In the example where the underlayer 405 is an organic material, the organic material may be a cross-linkable polymeric material that may be coated onto the substrate 400 through a spin-on process. The underlayer 405 can be thermally cured so that the photoresist layer 407 may be later applied thereon. In the example wherein the underlayer 405 is an inorganic material. The inorganic material may be a dielectric material formed by any suitable deposition techniques, such as CVD, ALD, PVD, spin-on-coating, spray coating or the like.

The underlayer 405 functions as a planarizing layer, an antireflective coat (ARC) and/or photoacid direction controller. The underlayer 405 provides etch resistance and line edge roughness control when transferring the pattern into the underlying hardmask layer 403 and the target layer 402. The patterning resistant functionality from the underlayer 405 may work with the underlying hardmask layer 403 during the transfer of the resist process. In one example, the underlayer 405 does not interact with the photoresist layer 407 and does not have interfacial mixing and/or diffusion or cross contamination with the photoresist layer 407.

The underlayer 405 includes one or more additives, such as acid agents, (e.g., photoacid generators (PAGs) or acid catalyst), base agents, adhesion promoters or photo-sensitive components. The one or more additives may be disposed in organic solvent or resin and/or an inorganic matrix material. Suitable examples of the acid agents including photoacid generators (PAGs) and/or acid catalyst selected from a group consisting of sulfonic acids (e.g., p-toluenesulfonic acid, styrene sulfonic acid), sulfonates (e.g., pyridinium p-toluenesulfonate, pyridinium trilluoromethanesulfonate, pyridinium 3-nitrobenzensulfonate), and mixtures thereof. Suitable organic solvent may include homo-polymers or higher polymers containing two or more repeating units and polymeric backbone. Suitable examples of the organic solvent include, but are not limited to, propylene glycol methyl ether acetate (PGMEA), ethyl lactate (EL), propylene glycol methyl ether (PGME), propylene glycol n-propyl ether (PnP), cyclohexanone, acetone, gamma butyrolactone (GBL), and mixtures thereof.

In one example, the underlayer 405 provides one or more additives, such as active acid agents, base agents or ionic/non-ionic species during the lithographic exposure process, pre- or post-exposure baking process, to assist in the control of the photoacid flowing direction from the photoresist layer 407. In one example, the additive includes photoacid. As explained in more detail below, one or more of the additives assist in movement of photoacid within photoresist layer 407, when the electric field or magnetic field is applied. In one example, movement of the photoacid includes migration of photoacid to or from the underlayer 405 to or from the photoresist layer 407.

The hardmask layer 403 may be the antireflective coat (ARC) layer fabricated from a group consisting of silicon oxide, silicon nitride, silicon oxynitride, silicon carbide, amorphous carbon, doped amorphous carbon, TEOS oxide, USG, SOG, organic silicon, oxide containing material titanium nitride, titanium oxynitride, combinations thereof and the like.

The photoresist layer 407 may be a positive-tone photoresist and/or a negative-tone photoresist that are capable of undergoing a chemically amplified reaction. The photoresist layer 407 is a polymer organic material.

As discussed above, an electric field from the electrode assembly 216, as well as a magnetic field from the magnets 296, may be applied during a lithography exposure process, pre- or post-exposure baking process, particularly, a post-exposure baking process. In the example depicted in FIG. 4, the electric field and/or and magnetic field is applied during the post-exposure baking process. During post-exposure baking process, a thermal energy is applied to the substrate 400 as well as the electric field and/or the magnetic field. Photoacid, shown as e⁻ in FIG. 4, is generated in a first region 408 in the photoresist layer 407 where the photoacid generator (PAG) therein has been exposed to a light radiation 412. In one example, the light radiation 412 is a UV light radiation from the previous lithography exposure process. Movement of photoacid may be random and a photoacid distribution may not be evenly distributed in the first region 408. Additionally, movement of photoacid may not have a clear boundary set at an interface 430 formed in a plane (interfaced with a second region 406). The interface 430 is the plane defined between the first region 408 and the second region 406. As shown by an arrow 422, a portion of photoacid may drift and diffuse into the second region 406, the second region 406 unintended to have photoacid generation. As such, lateral photoacid movement (e.g., a direction parallel to a planar surface of the substrate 400) can drift into the second region 406, as shown by the arrow 422. Such lateral photoacid movement may result in line edge roughness, resolution loss, photoresist footing, profile deformation, causing inaccurate feature transfer to the underlying target layer 402 and/or eventually leading to device failure.

Although the example discussed herein is illustrates the movement of electrons from the photoacid, it is noted that any suitable species, including charges, charged particles, photons, ions, electrons, or reactive species in any forms, may also have similar effects when the electric field is applied to the photoresist layer 407.

By applying an electric field to the photoresist layer 407 during the post-exposure baking process, distribution of photoacid in the exposed first region 408 may be efficiently redirected, controlled, and confined. Alternatively, by applying a magnetic field to the photoresist layer 407 during the post-exposure baking process, distribution of photoacid in the exposed first region 408 may be efficiently redirected, controlled, and confined along field lines of the electric field or magnetic field. Applying the electric field or magnetic field to distribute the photoacid, as described herein, mitigates the stochastic effects within the photoresist. In another example, the electric field and magnetic field distribute the photoacid within the photoresist layer 407.

The electric field, as applied to the photoresist layer 407, can move photoacid in a vertical direction (e.g., y direction shown by arrows 416 and 420 substantially perpendicular to the planar surface of the substrate 400). The electric field can move photoacid in the vertical direction with minimal lateral motion (e.g., x direction shown by the arrow 422), and without diffusing into the adjacent second region 406. Photoacid may have a certain polarity that can be effected by the electric field or magnetic field applied thereto. The electric field or magnetic field can orient photoacid in a given direction, creating a desired directional movement of the photoacid in the exposed first region 408 without crossing into the adjacent protected second region 406. Furthermore, photoacid dose sensitivity, photon absorption efficiency, sensitivity enhancement of the underlayer 405 and stochastic effects within the photoresist can be controlled and mitigated by applying proper process parameters of the electric field and/or magnetic field during the post-exposure baking process. Furthermore, a photoresist line edge roughness and line critical dimension uniformity may also be well controlled, enhanced and improved when performing the post-exposure baking process.

In one example, the photoacid may further be controlled to move directionally at a longitudinal direction (e.g., z direction shown by arrow 428, defined in a plane interfaced with the second region 406 of the photoresist layer 407 protected by the photomask 410) along a lateral plane, as shown by arrow 414. As shown by arrow 422, a longitudinal distribution of photoacid can be confined in the exposed first region 408 without crossing at the x direction into the second region 406 of the photoresist layer 407. The magnetic field generated to the photoresist layer 407 may cause the electrons to orbit along a magnetic line, such as the longitudinal direction (e.g., z direction shown by arrow 428) so as to further control the photoacid in a desired three-dimensional distribution. An interaction between the magnetic field and the electric field may optimize a trajectory of photoacid along a path as desired and confined in the exposed first region 408. Otherwise stated, electric field directs the trajectory of the photoacid along the path by confining movement of the photoacid along field lines or lines of force within the electric field. In another example, the magnetic field directs the trajectory of the photoacid along the path along field lines of the magnetic field, in substantially the same manner as the electric field. The path can include trajectories along the x-direction, y-direction, and z-direction. Furthermore, vertical photoacid movement is desired to smooth out standing waves that are naturally produced by a light exposure tool (not shown), thus enhancing exposure resolution.

In one example, the electric field having a strength between about 100 MV/m and about 2000 MV/m may be applied to the photoresist layer 407, during the post-exposure baking process. The electric field can confine photoacid generated in the photoresist layer 407 in a vertical direction, e.g., along a y direction. In one example, the magnetic field having a strength between 5 Tesla (T) and 500 Tesla (T), along with the electric field, may be applied to the photoresist layer 407, during a post-exposure baking process. The magnetic field can confine photoacid generated in the photoresist layer 407 in both longitudinal direction and vertical direction, e.g., along y and z directions, with minimum lateral direction, e.g., along the x direction. While combining the magnetic field along with the electric field, the photoacid as generated may be further confined to be distributed in the longitudinal direction, e.g., in the direction shown by the arrow 428. The photoacid may remain in the first region 408 of the photoresist layer 407, parallel to the interface 430 within the exposed first region 408.

In one example, the electric field and the magnetic field may be applied separately. For example, the electric field applied during the post-exposure baking process may be controlled in a manner that can confine the movement of the photoacid a given direction. In one example, during the post-exposure baking process, the voltage power as supplied to generate the electric field may be controlled in a range between about 100 volts and about 5000 volts, such as between about 100 volts and about 1000 volts. Furthermore, the voltage power as applied may be in continuous mode or in pulse mode. In one example, the voltage power as applied to generate the electric field is in pulse mode. In another example, the voltage power as supplied for generating the electric field may be pulsed between about 5% and about 75% of each duty cycle. Each duty cycle, for example between each time unit, is between about 0.1 seconds and about 10 seconds, such as about 5 seconds.

Furthermore, during the post-exposure baking process, the thermal energy supplied to the substrate 400, further to the photoresist layer 407, may be controlled in a manner that can also assist in confining the photoacid movement in the photoresist layer 407. As noted, the photoacid movement is confined along field lines of the electric field or magnetic field. The thermal energy may be supplied by controlling the embedded heater 232 disposed in the substrate support assembly 238. In one example, the temperature of the substrate 400 may be controlled at between about 10 degrees Celsius (such as room temperature) and about 130 degrees Celsius, such as about 120 degrees Celsius. Thermal energy supplied during the post-exposure baking process may enhance the kinetic energy or the momentum of the electrons driven by the electric and/or magnetic fields so that the control efficiency of the photoacid movement may be enhanced. Otherwise stated, thermal energy increases the mobility of the photoacid with the photoresist layer 407 as thermal energy imparts momentum or kinetic energy to the photoacid. Application of the electric field or magnetic field during the post-exposure baking process is used to controls the trajectory of the photoacid within the photoresist layer 407.

In some examples, the thermal energy supplied to the substrate 400 may be prior to, synchronized, or after the time point when the electric field and/or magnetic field are supplied. In one example, the thermal energy (e.g., turning on the heaters 232 in the substrate support assembly 238 where the substrate 400 is placed) is supplied to the substrate 400 prior to applying the electric field and/or the magnetic field to the substrate 400. It is believed that the thermal energy supplied prior to the electric field and/or the magnetic field may assist activating the electrons in an active state, so that the electrons may be relatively easier to confine or accelerate along a predetermined path. The thermal energy supplied thus enhances the electrical performance of the photoresist layer during the post-exposure baking process. The post-exposure baking process may include a photon absorption efficiency, dose sensitivity, or drift directionality control. Accordingly, the electric field can be applied to the substrate 400 during the post-exposure baking process. Alternatively, during the post-exposure baking process, the magnetic field is applied to the substrate 400. As electrons are activated and/or driven not only by the electric field/magnetic field, but also by the thermal energy, the total process time, such as the total time for performing the post-exposure baking process, may be reduced to a range between about 5% and about 40% less than the process time for only applying the thermal energy during the post-exposure baking process. In another example, the range can be about 20%, less than the process time for only applying the thermal energy during the post-exposure baking process.

FIG. 5 depicts another profile of photoacid distribution that may be controlled by utilizing an electric field, magnetic field, thermal energy from the substrate 400 or combinations thereof to specifically control the photoacid located at certain zones during a post-exposure baking process. An exposed region 502 of the photoresist layer 407 has chemically altered from the first region 408 after the lithographic exposure process. After the photoresist layer 407 is lithographically exposed, a post-exposure baking process is then performed to cure (e.g., providing thermal energy to the substrate 400 from the substrate support assembly, as shown by arrow 508). The post-exposure baking process includes curing the photoresist layer 407, including the exposed region 502, and the remaining regions (e.g., shielded by the photomask during the lithographic exposure process) in the photoresist layer 407. During the post-exposure baking process, the acid agent (e.g., such as photoacid), base agent, or other suitable additive(s) from the underlayer 405 may be controlled in a manner that can assist distribution/movement of the photoacid within the photoresist layer 407 in a desired direction, as shown by the arrow 506 in FIG. 5. Additionally, the acid agent (e.g., such as photoacid), base agent, or other suitable additive(s) can be driven by the thermal energy from the substrate 400. The additive(s) in the underlayer 405 is diffused to an upper photoresist layer 504 during the post-exposure baking process (or even during the lithographic exposure process). Diffusing the additive(s) in the underlayer 405 helps to improve the sensitivity of the photoresist layer 407 in order to maintain a vertical profile of the photoresist layer 407. As a result, after development and rinse, a substantially vertical profile may be obtained in the photoresist layer 407.

In one example, the additive(s), such as acid agents or photoacid as one example, from the underlayer 405 may be thermally driven upwards, as shown by the arrow 506, during the post-exposure baking process so that the profile of the photoresist layer 407 may be efficiently controlled. Furthermore, as the additives from the underlayer 405 may be driven at a particular direction upward by the electric field, magnetic field, or combinations thereof during the post-exposure baking process. The electrons provided from the additives may be controlled along the path. In one example, the path is predominantly in a vertical direction toward the photoresist layer 407. By doing so, the desired vertical structure may be defined and confined in the photoresist layer 407. It is noted that the examples of the photoresist layer 407 depicted in FIGS. 4-5 are formed with a straight edge profile (e.g., a vertical sidewall). However, the profile of the photoresist layer 407 may be formed in any desired shapes, such as a tapered or flare-out opening.

After the post-exposure baking process, an anisotropic etching process, or other suitable patterning/etching processes, may be performed to transfer features into the underlayer 405, the hardmask layer 403 and the target layer 402.

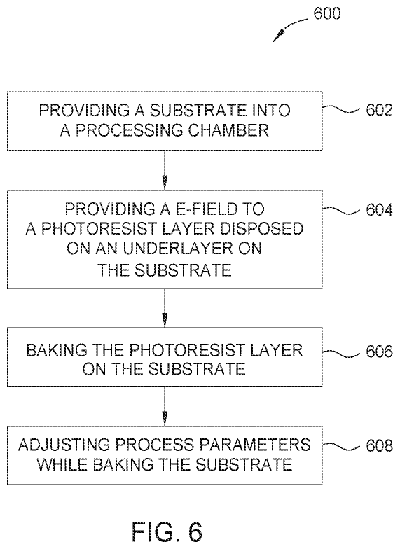

FIG. 6 depicts a flow diagram of a method 600 for utilizing electric field and magnetic field to assist controlling photoacid distribution/diffusion in a photoresist layer during a pre- or a post-exposure baking process. Distribution or diffusion of photoacid is controlled within the photoresist layer by application of electric field or magnetic field. Because the photoacid is charged, the photoacid moves along field lines of either the electric field or magnetic field. The method 600 beings at operation 602 by positioning a substrate, such as the substrate 400 described above, into a processing chamber, such as the processing chamber 200 depicted in FIGS. 2-3, with an electrode assembly and a magnetic assembly disposed therein.

At operation 604, after the substrate 400 is positioned, an electric field and/or a magnetic field may be individually or collectively applied to the processing chamber (during a lithographic exposure process and/or post-exposure baking process) to control photoacid movement within in a photoresist layer having an underlayer disposed thereunder. It is noted that the electric field and/or the magnetic field may be applied simultaneous, prior to, or after baking the substrate 400, as will be further discussed at operation 606. Otherwise stated, the electric field and/or a magnetic field individually or collectively applied to the substrate at operation 604 may be performed prior to or after the baking process at operation 606 as needed.

After the electric field and/or a magnetic field is individually or collectively applied to the photoresist layer and the underlayer disposed on the substrate, photoacid as generated may move primarily in a vertical direction, a longitudinal direction, a circular direction, rather than a lateral direction. As a result of the assistance provided by the electric field and/or a magnetic field during the baking process, the photoacid movement in the photoresist layer may be efficiently controlled.

At operation 606, a thermal energy is provided to bake (e.g., cure) the photoresist layer. During the baking process, an energy (e.g., an electric energy, thermal energy or other suitable energy) may also be provided to the photoresist layer as well as the underlayer. In one example depicted herein, the energy is a thermal energy provided to the substrate during the post-exposure baking process as well as the electric field and/or the magnetic field applied at operation 604. The additives from the underlayer may also assist controlling the flow direction of the photoacid within the photoresist layer. As noted above, additives can be charged species and therefore are capable of moving along the field lines of the electric field or magnetic field. In one example, additives from the underlayer can migrate to the photoresist layer. In another example, charged species from photoresist layer can migrate to the underlayer. In at least one example, the charged species includes a photoacid. Photoacid concentration within the photoresist layer is modulated by migration of the additives, including the charged species, to and from the underlayer. By utilizing directional control of photoacid distribution along the predetermined path having a patterned photoresist layer with the assistance from the electric field and/or a magnetic field, a desired edge profile with high resolution, does sensitivity, resistance to line collapse, and stochastics failure, and minimum line edge roughness may be obtained. The photoacid, quencher, ions, electron, and other charge species in the photoresist layer may be efficiently guided so as to move in desired directions. Thus, the benefits of applying the electric field and/or magnetic field during the post-exposure baking process include photoresist stochastics improvement, measurement with LER (line edge roughness), LWR (line width roughness), LCDU (local critical dimension uniformity), critical dimension viability and nano-defect (such as resist scumming, line merge, line breaking and the like) reduction. As detailed above, the methods disclosed herein advantageously mitigate stochastic effects in the patterned photoresist layer. Beneficially, the device yield is improved.

At operation 608, while baking the photoresist layer as well as applying the electric field and/or the magnetic field to the photoresist layer at operation 604 and 606, the process parameters utilized to control the thermal energy, electric field and/or the magnetic field may be altered or adjusted as needed. For example, the power utilized to control the electric field and/or the magnetic field may be switched, changed, altered or adjusted during the baking process. In one example, the power supplied to control the electric and/or the magnetic field may be in continuous mode, pulsed mode, or a combination of mixed continuous or pulsed mode as needed. It is noted that operation 604, 606 and 608 could be in any order as needed when performing the post-exposure baking process during the method 600.

The previously described examples have many advantages, including the following. For example, the examples disclosed herein may reduce or eliminate line edge/width roughness with high resolution and sharp edge profile by applying electric and/or magnetic field during a post-exposure baking process. The aforementioned advantages are illustrative and not limiting. It is not necessary for all examples to have all the advantages.

While the foregoing is directed to examples of the present disclosure, other and further examples of the disclosure may be devised without departing from the basic scope thereof, and the scope thereof is determined by the claims that follow.

What is claimed is:

1. A method of processing a substrate, the method comprising:
applying a photoresist layer comprising a photoacid generator to a multi-layer disposed on the substrate, wherein the multi-layer comprises an underlayer;
exposing a first portion of the photoresist layer unprotected by a photomask to a radiation light in a lithographic exposure process;
providing a thermal energy to the photoresist layer and the multi-layer in a post-exposure baking process, the multi-layer disposed beneath the photoresist layer;
applying an electric field or a magnetic field to photoresist layer and the multi-layer while performing the post-exposure baking process; and
driving an additive within the underlayer in a vertical direction into the photoresist layer, wherein the additive assist in distribution of a photoacid throughout the photoresist layer during the post-exposure baking process.

2. The method of claim 1, wherein the underlayer is formed from an organic material, inorganic material, or a mixture of organic and inorganic materials.

3. The method of claim 1, wherein distribution of a photoacid throughout the photoresist layer changes one or more of photoresist line edge roughness, resist scumming, line merge, line breaking, critical dimension viability and line critical dimension uniformity while performing the post-exposure baking process.

4. The method of claim 1, wherein applying the electric field or the magnetic field further comprises:
applying a voltage power in a pulse mode to generate the electric field.

5. The method of claim 1, wherein a strength of the electric field is controlled between about 100 MV/m and about 2000 MV/m during the post-exposure baking process.

6. The method of claim 2, wherein multi-layer further comprises:
a hardmask layer disposed beneath the underlayer, the hardmask layer disposed on top of a target layer, wherein the underlayer includes one or more additives in an organic polymer solvent.

7. The method of claim 6, wherein the additives are selected from a group consisting of acid agents, base agents, adhesion promoters and photo-sensitive components.

8. The method of claim 1, wherein applying the electric field or the magnetic field further comprises:
controlling the magnetic field at a range between about 5 Tesla (T) and about 500 Tesla (T); or
controlling the electric field between about 100 MV/m and about 2000 MV/m.

9. The method of claim 2, wherein the multi-layer further comprises a hardmask layer disposed under the underlayer and above the substrate.

10. The method of claim 1, wherein providing the thermal energy to the photoresist layer further comprises:
controlling a substrate temperature at between about 10 degrees Celsius and about 130 degrees Celsius.

11. A method of processing a substrate, the method comprising:
applying a photoresist layer disposed on the substrate, the substrate having a multi-layer disposed thereon;
exposing a first portion of the photoresist layer unprotected by a photomask to a radiation light in a lithographic exposure process;
performing a post-exposure baking process on the photoresist layer;
supplying a power in a pulse mode to generate an electric field while performing the post-exposure baking process; and
vertically diffusing an additive in the multi-layer into the photoresist layer, wherein the additive assist in distribution of a photoacid throughout the photoresist layer during the post-exposure baking process.

12. The method of claim 11, wherein exposing the first portion of the photoresist layer further comprises:
applying an electric field or a magnetic field while performing the lithographic exposure process.

13. The method of claim 11, wherein applying the photoresist layer further comprises:
applying a photoacid generator to the multi-layer disposed on the substrate, the multi-layer including an underlayer in contact with the photoresist layer, wherein the underlayer is an organic material.

14. The method of claim 11, wherein a strength of the electric field is controlled between about 100 MV/m and about 2000 MV/m during the post-exposure baking process.

15. The method of claim 11, wherein performing the post-exposure baking process on the photoresist layer further comprises:
controlling a magnetic field at a range between about 5 Tesla (T) and about 500 Tesla (T) during the post-exposure baking process.

16. The method of claim 11, wherein applying the electric field while performing the post-exposure baking process further comprises:
altering movement of photoacid generated in the photoresist layer substantially in a vertical direction.

17. The method of claim 11, wherein performing the post-exposure baking process on the photoresist layer further comprises:
controlling a substrate temperature at between about 10 degrees Celsius and about 130 degrees Celsius.

18. A method of processing a substrate, the method comprising:
applying a photoresist layer on a underlayer disposed on the substrate, wherein the underlayer is an organic material;
exposing a first portion of the photoresist layer unprotected by a photomask to a radiation light in a lithographic exposure process;
providing an thermal energy to the photoresist layer and the underlayer disposed on the substrate in a post-exposure baking process;
supplying a power in a pulse mode to generate an electric field while performing the post-exposure baking process; and
orienting a photoacid formed in the first portion of the photoresist layer while generating the electric field to the photoresist layer, wherein the photoacid is oriented by vertical movement of an additive in the underlayer, the additive vertically diffused from the underlayer to the first portion of the photoresist layer.

19. The method of claim 18, wherein a strength of the electric field is controlled between about 100 MV/m and about 2000 MV/m during the post-exposure baking process.

20. The method of claim 19, wherein providing the thermal energy to the photoresist layer in the post-exposure baking process further comprises:
controlling a substrate temperature at between about 10 degrees Celsius and about 130 degrees Celsius.
